(19) United States
(12) Patent Application Publication
(10) Pub. No.: US 2025/0275365 A1
(43) Pub. Date: Aug. 28, 2025

(54) LIGHT EMITTING DISPLAY DEVICE

(71) Applicant: LG Display Co., Ltd., Seoul (KR)

(72) Inventors: Dae Hwan KIM, Paju-si (KR); Deuk Ho YEON, Paju-si (KR); Do Hun KWAK, Paju-si (KR)

(73) Assignee: LG Display Co., Ltd., Seoul (KR)

(21) Appl. No.: 19/060,418

(22) Filed: Feb. 21, 2025

(30) Foreign Application Priority Data
Feb. 27, 2024 (KR) 10-2024-0028396

(51) Int. Cl. H10K 59/121; H10D 86/40; H10K 59/126

(52) U.S. Cl. CPC H10K 59/1213; H10D 86/423; H10K 59/126

(57) ABSTRACT

Disclosed is a light emitting display device, including a substrate having a first area and a second area, first emissive portions provided in the first area, second emissive portions and transmissive portions provided in the second area, a first transistor provided in the first area and including a first active pattern and a first gate electrode overlapping the first active pattern, and a second transistor provided in the second area and including a second active pattern having higher average mobility than the first active pattern and multiple interfaces having differences in mobility and a second gate electrode overlapping the second active pattern.

### CROSS-REFERENCE TO RELATED APPLICATION(S)

This application claims the benefit of Korean Patent Application No. 10-2024-0028396, filed on Feb. 27, 2024, which is hereby incorporated by reference as if fully set forth herein.

### BACKGROUND

### Technical Field

The present disclosure relates to transistors, and more particularly to a light emitting display device including transistors capable of improving luminance and reliability.

### Description of the Related Art

Display devices that display images, such as TVs, monitors, smartphones, tablet computers, and laptops, are used in various ways and forms.

The display device includes a plurality of pixels to display an image and has transistors to control the operation of each pixel.

The display device includes a plurality of pixels and is provided with multiple driving and switching devices to drive and control the pixels. Driving and switching devices may be composed of transistors, and the transistors are widely employed in integrated circuits as well as the pixels.

Recently, thorough research and development is ongoing to improve performance and reliability of the transistors.

### BRIEF SUMMARY

Various embodiments of the present disclosure provide a light emitting display device that enables selective mobility control per area by varying the average mobility of active layers for each area.

Various embodiments of the present disclosure provide a light emitting display device, in which a high-mobility active layer is included in transistors including oxide semiconductors, improving mobility, and also increasing reliability by improving sensitivity to light by a multilayer structure.

Various embodiments of the present disclosure provide a light emitting display device, in which a high-mobility active layer is further included in a sensor portion having transistors arranged at a relatively low density, improving mobility of the transistors located in the sensor portion, thereby obtaining high luminance.

Various embodiments of the present disclosure provide a light emitting display device, in which the thickness of a buffer layer of transistors in a sensor portion is reduced by adjusting the position of the high-mobility active layer added to the transistors of the sensor portion, increasing the S-factor, thereby enabling low-gradation expression.

Various embodiments of the present disclosure provide a light emitting display device with improved optical reliability and reduced failure rate of transistors, in which active patterns having different structures may be manufactured through the same process, thereby reducing the amounts of materials used throughout the manufacturing process such as gases, etchants, etc., for manufacturing display devices, and also, reducing greenhouse gas emissions during the manufacturing process and achieving process optimization.

An embodiment of the present disclosure provides a light emitting display device, including a substrate having a first area and a second area, first emissive portions provided in the first area, second emissive portions and transmissive portions provided in the second area, a first transistor provided in the first area and including a first active pattern and a first gate electrode overlapping the first active pattern, and a second transistor provided in the second area and including a second active pattern having higher average mobility than the first active pattern and multiple interfaces having differences in mobility and a second gate electrode overlapping the second active pattern.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a schematic plan view showing a light emitting display device according to an embodiment of the present disclosure;

FIG. 2 is a circuit diagram showing a sub-pixel according to an embodiment of the present disclosure;

FIG. 3 is an enlarged view of area A of FIG. 1;

FIG. 4 is a cross-sectional view showing transistors in the first and second areas of FIG. 3;

FIG. 5 is a view showing a current path between active layers and an adjacent gate insulating film in a light emitting display device according to an embodiment of the present disclosure;

FIG. 6 is a graph showing the Ids-Vgs relationship in a structure with a difference in thickness between a light blocking pattern and an active layer in a driving transistor;

FIGS. 7A to 7D are cross-sectional views showing a process of manufacturing a light emitting display device according to an embodiment of the present disclosure; and

FIG. 8 is a cross-sectional view showing a light emitting display device according to an embodiment of the present disclosure.

### DETAILED DESCRIPTION

Hereinafter, preferred embodiments of the present disclosure will be described with reference to the attached drawings. The same reference numerals indicate substantially the same elements throughout the specification. In the following description of the present disclosure, where the detailed description of the relevant known steps, elements, functions, technologies, and configurations can unnecessarily obscure an important point of the present disclosure, a detailed description of such steps, elements, functions, technologies, and configurations may be omitted. In addition, the names of elements used in the following description are selected in consideration of clarity of description of the specification, and can differ from the names of elements of actual products.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In the present disclosure, where terms such as “including,” “having,” “comprising,” and the like are used, one or more components can be added, unless the term, such as “only,” is used. The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

The term “in contact with,” as used herein, encompasses both “indirect contact” and “direct contact.” Accordingly, when the phrase “A is in contact with B” is used, it implies that other components may be present between A and B, unless explicitly specified as “A is in direct contact with B.”

In describing the various example embodiments of the present disclosure, where the positional relationship between two elements is described using terms, such as “on,” “above,” “under” and “next to,” at least one intervening element can be present between the two elements, unless “immediate(ly)” or “direct(ly)” or “close(ly) is used. It will be understood that when an clement or layer is referred to as being “connected to,” or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

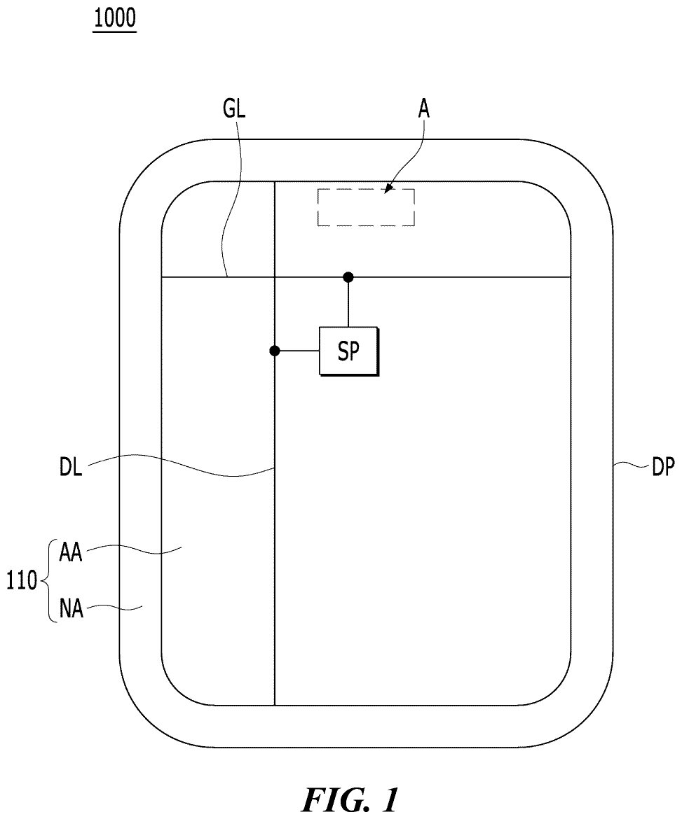

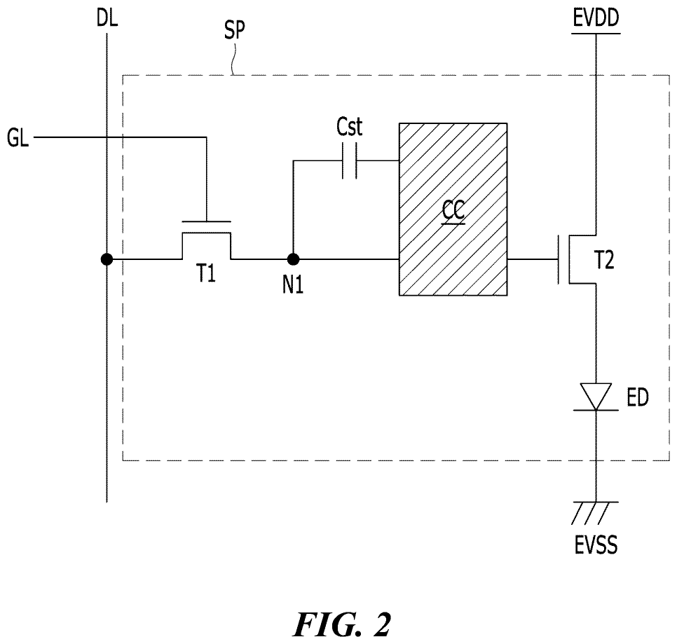

FIG. 1 is a schematic plan view showing a light emitting display device according to an embodiment of the present disclosure. FIG. 2 is a circuit diagram showing a sub-pixel according to an embodiment of the present disclosure.

Referring to FIGS. 1 and 2, a light emitting display device 1000 according to an embodiment of the present disclosure may include a display panel DP and a case (not shown) that accommodates a side of the display panel DP and a bottom of the display panel DP. The non-active area NA of the display panel DP may be hidden by the case or may be covered with a separate light blocking film. A printed circuit film and/or a battery may be included between the bottom of the display panel DP and the case.

The display panel DP may include a substrate 110 including an active area AA and a non-active area NA surrounding the active area AA, and a driver connected to the substrate 110. The driver may be formed by being integrated into the substrate 110 together with components in the array provided in the active area AA, or may be connected to the substrate 110 in a COG (chip on glass) manner or may be connected to a printed circuit board through a film or connector in a COF (chip on film) manner on the substrate 110. Alternatively, the driver may also include components integrated into the substrate 110 and external components of COG or COF.

The active area AA is the area where the image is displayed. A plurality of sub-pixels SP is arranged in the active area AA of the display panel DP, and an image may be displayed using the sub-pixels SP. The area other than the active area AA may be a non-active area NA.

The non-active area NA may be disposed in the edge surrounding the active area AA that displays the image. At least one driver configured to drive the sub-pixels SP may be disposed in the non-active area NA. The driver may include a gate-in-panel GIP. The gate-in-panel GIP may be connected to a plurality of gate lines GL of the active area AA and may serve to sequentially supply gate voltage signals to the gate lines GL.

In the non-active area NA, various additional elements may be further disposed to drive the sub-pixels SP in the active area AA.

At least one sub-pixel SP among a plurality of pixels may include a first transistor T1, a second transistor T2, a storage capacitor Cst, a compensation circuit CC, and a light emitting device ED, as shown in FIG. 2.

For example, the first transistor T1 may be a switching transistor and the second transistor T2 may be a driving transistor.

A first electrode (e.g., a drain electrode) of the first transistor T1 is electrically connected to a data line DL, and a second electrode (e.g., a source electrode) thereof is electrically connected to a first node N1. The gate electrode of the first transistor T1 is electrically connected to a gate line GL. The first transistor T1 serves to transmit a data signal supplied through the data line DL to the first node N1 in response to a scan signal supplied through the gate line GL.

The storage capacitor Cst is electrically connected to the first node N1 and serves to charge the voltage applied to the first node N1.

A first electrode (e.g., a drain electrode) of the second transistor T2 receives a high potential driving voltage EVDD, and a second electrode (e.g., a source electrode) thereof is electrically connected to a first electrode (e.g., an anode) of the light emitting device ED. The second transistor T2 may serve to control the quantity of driving current flowing to the light emitting device ED depending on a difference in voltage between the gate electrode and the source electrode.

The semiconductor layer of the first transistor T1 and/or the second transistor T2 may include silicon such as amorphous silicon (A-Si), polycrystalline silicon (poly-Si), or low-temperature polycrystalline silicon (poly-Si), or may include an oxide semiconductor.

The transistors and display device according to embodiments of the present disclosure may be advantageous in that an oxide semiconductor layer is included in at least one of the transistors formed on the substrate 110, enabling formation at a low temperature compared to other materials, maintaining amorphous characteristics, and exhibiting high mobility.

The light emitting device ED serves to output light corresponding to the driving current. The light emitting device ED is able to output light corresponding to any one color selected from among the colors red, green, blue, and white.

The light emitting device ED may include an anode, an intermediate layer disposed on the anode, and a cathode configured to supply a common voltage. The intermediate layer includes at least one emission layer, and when an electric field is formed between the anode and the cathode, it is possible to emit light of the same color for each pixel, such as white light, or to emit light of a different color for each sub-pixel SP, such as red, green, or blue light. The intermediate layer may include various types of common layers and functional layers to efficiently supply holes and electrons to the emission layer, in addition to the emission layer.

The light emitting device ED may be a top emission diode or a bottom emission diode.

The compensation circuit CC may be additionally provided in the sub-pixel SP to compensate for the threshold voltage of the second transistor T2, etc. The compensation circuit CC may be composed of one or more transistors. The compensation circuit CC may include one or more transistors and capacitors and may be configured in various ways depending on the compensation method. A sub-pixel SP including the compensation circuit CC may include circuits with various structures having different numbers of transistors and/or capacitors, such as 3T1C, 4T2C, 5T2C, 6T1C, 6T2C, 7T1C, 7T2C, etc.

Among the transistors provided in the sub-pixel, the switching transistor may require high speed driving for fast switching operation. The driving transistor may require high current output for high luminance expression by supplying high current to the light emitting device.

The non-active area NA may include a gate-in-panel GIP. The gate-in-panel GIP serves to output gate signals to gate lines in response to a gate control signal input from, for example, a timing controller. The gate-in-panel GIP may include a plurality of transistors, which may be formed through the same process as the transistors of the sub-pixel SP.

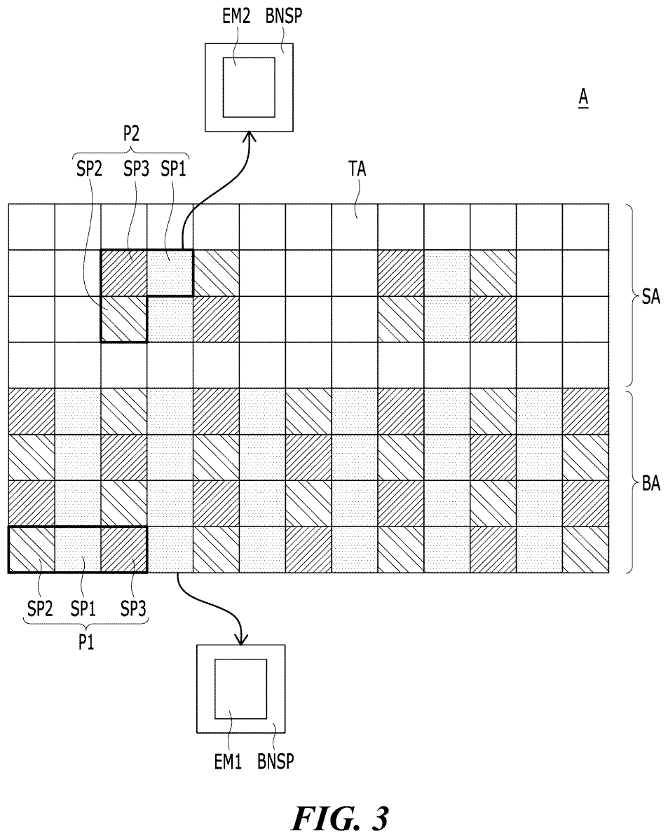

FIG. 3 is an enlarged view of area A of FIG. 1.

The display panel DP may be provided with a camera or sensor at the lower side of the substrate 110, as in area A of FIG. 1. The camera or sensor may be provided at the lower side of the substrate 110 while overlapping the substrate 110. As shown in FIG. 1, area A is included in the active area AA.

Referring to FIG. 3, area A includes a first area BA in which sub-pixels SP1, SP2, SP3 are regularly arranged at a first arrangement density, and a second area SA in which sub-pixels SP1, SP2, SP3 are arranged at a second arrangement density less than the first arrangement density by providing a camera or sensor and further providing transmissive portions TA for receiving light from the camera or sensor or transmitting light from the top to the camera or sensor.

The area A is located in the active area AA, and one or more second areas SA where the camera or sensor is located may be locally disposed in the active area AA. Also, the first area BA is located surrounding each of one or more second areas SA.

To be more specific, in the first area BA, each first pixel P1 is used as a unit, which includes three sub-pixels SP1, SP2, SP3 emitting light of different colors respectively, and first pixels P1 are uniformly arranged without any gap therebetween.

In the second area SA, each second pixel P2 is used as a unit, which includes three sub-pixels SP1, SP2, SP3 emitting light of different colors respectively. Here, second pixels P2 are densely arranged in some regions, and the remaining regions are left empty to function as transmissive portions TA.

Each of the sub-pixels SP1, SP2, SP3 of the first and second pixels P1, P2 in the first and second areas BA, SA may include the transistors and the light emitting device ED described in FIG. 2.

The second pixels P2 are provided along with the transmissive portions TA in the second area SA and have a second resolution lower than the first resolution of the first pixels P1.

Here, the second area SA is provided with second pixels P2 having a lower resolution than the first pixels P1 of the first area BA, and since no transistor is provided in the regions occupied by the transmissive portions TA in the second area SA, the transistor arrangement density per area is lower than that of the first area BA. Accordingly, in order to exhibit the same emission characteristics as the first area BA, the transistors TFT of the second area SA may have higher sensitivity than the transistors P1_T of the first area BA. As such, the mobility of the transistors P2_T of the second area SA may be higher than the mobility of the transistors P1_T of the first area BA. For example, the semiconductor layers of the transistors in the first area BA and the second area SA may be formed of different materials to obtain a difference in mobility.

Meanwhile, the transistors provided in each of the sub-pixels of the first and second areas BA, SA may require different mobility characteristics. For example, the switching transistors, which require fast response, may have higher mobility than the driving transistors for gradation expression.

As shown in FIG. 3, the light emitting display device according to an embodiment of the present disclosure includes a substrate 100 having a first area BA and a second area SA, first emissive portions EM1 provided in the first area BA, second emissive portions EM2 and transmissive portions TA provided in the second area SA and spaced apart from each other, and a pixel definition layer BNSP surrounding each of the first emissive portions EM1 and the second emissive portions EM2.

Since the transmissive portions TA of the second area SA are not provided with transistors, light from the top of the substrate 110 may pass through to the lower side of the substrate 110 as is, or light from the sensor or camera located at the lower side of the substrate 110 may be transmitted to the top of the substrate 110.

In the transmissive portion TA, a component that reflects or blocks light among the components of the light emitting device ED may be omitted. For example, when the light emitting device ED includes an anode, an intermediate layer, and a cathode and when the anode or the cathode is a reflective electrode, the reflective electrode may be removed from the transmissive portion TA. In some cases, some components of the intermediate layer may be removed from the transmissive portion TA to increase transmittance of the transmissive portion TA.

Each of the sub-pixels SP1, SP2, SP3 of the first and second areas BA, SA may include a pixel definition layer BNSP defining each of the emissive portions EM1, EM2 to transmit light from the light emitting device ED. The pixel definition layer BNSP may include bank and spacer structures, and the pixel definition layer BNSP may have a shape that opens each of the emissive portions EM1, EM2 while surrounding each of the emissive portions EM1, EM2. The pixel definition layer BNSP may be in a matrix form. The pixel definition layer BNSP may be removed from the region corresponding to the transmissive portion TA.

Among the components on the substrate 110, the transmissive portion TA may further include transmissive insulating films.

Meanwhile, the sub-pixels SP1, SP2, SP3 of the first and second areas BA, SA may include transistors P1_T, P2_T and capacitors and may be driven thereby, as shown in FIG. 2.

In the second area SA, the transmissive portions TA are provided, and transistors including metal are not disposed in the transmissive portions TA for transmittance. Accordingly, the transistors P2_T of the second area SA are disposed only in the sub-pixels SP1, SP2, SP3 of the second pixel P2 arranged in a limited manner. In the second area SA, the light emitting device is driven only with the transistors disposed in the sub-pixels SP1, SP2, SP3 of the second pixel P2 arranged in a limited manner, and the light emitting intensity of the area corresponding to the second area SA including the transmissive portions TA has to be adjusted. In order to exhibit the same luminance in the first area BA and the second area SA without a decrease in the luminance in the second area SA, the driving current intensity required for the transistors P2_T located in the second area SA may be greater than the driving current intensity required for the transistors P1_T located in the first area BA.

For example, when the arrangement density of the transistors P2_T in the second area SA is 40% of the arrangement density of the transistors P1_T in the first area BA, the transistors P2_T in the second area SA require current intensity that is at least two times that of the transistors P1_T in the first area BA.

A light emitting display device according to an embodiment of the present disclosure described below is capable of obtaining at least a certain level of mobility by changing the structure of transistors in the first area and the second area and also of obtaining characteristics corresponding to high luminance and high current driving of the transistors in the second area.

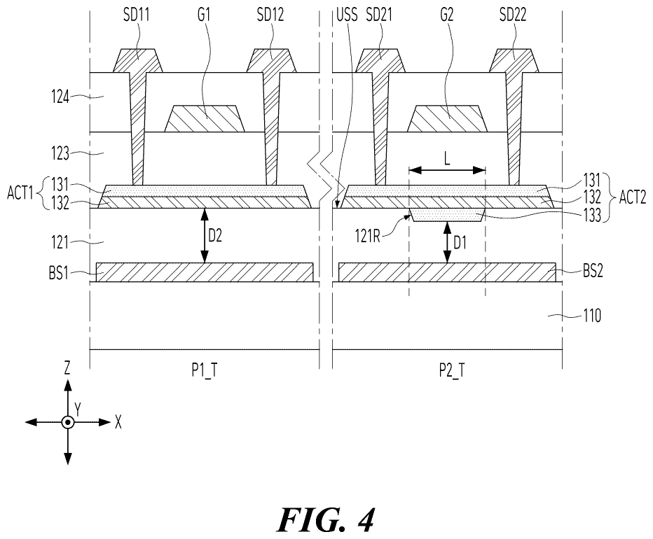

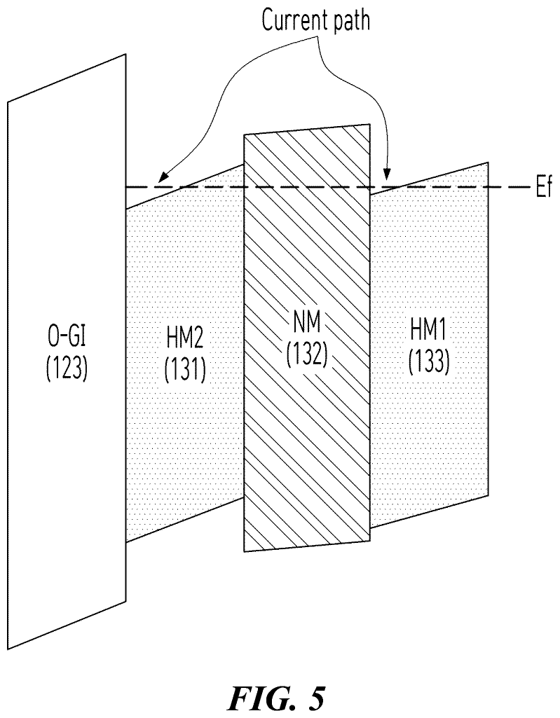

FIG. 4 is a cross-sectional view showing transistors in the first and second areas of FIG. 3. FIG. 5 is a view showing a current path between active layers and an adjacent gate insulating film in the light emitting display device according to an embodiment of the present disclosure.

As shown in FIGS. 3 and 4, the light emitting display device according to an embodiment of the present disclosure includes a substrate 110 having a first area BA (FIG. 3) and a second area SA (FIG. 3), first emissive portions EM1 provided in the first area BA, and second emissive portions EM2 and transmissive portions TA provided in the second area SA, in which each of the sub-pixels SP1, SP2, SP3 of the first area BA includes a first transistor P1_T and each of the sub-pixels SP1, SP2, SP3 of the second area SA includes a second transistor P2_T.

The first and second transistors P1_T, P2_T, each including multiple active layers, may be manufactured through the same process.

Each of the first active pattern ACT1 and the second active pattern ACT2 of the first and second transistors P1_T, P2_T may be made of an oxide semiconductor. Specifically, each of the first and second active patterns ACT1, ACT2 may be formed of an oxide semiconductor resulting from binding of at least one metal and oxygen. For the oxide semiconductor, it is possible to omit the high temperature crystallization process required for formation of polysilicon, etc., and to reduce generation of greenhouse gases and harmful gases during crystallization, enabling process optimization.

The first transistor P1_T includes a first active pattern ACT1 and a first gate electrode G1 overlapping the first active pattern ACT1 on the substrate 110. The first transistor P1_T may include first and second source/drain electrodes SD11, SD12 spaced apart from each other at both sides with the first gate electrode G1 therebetween.

The first active pattern ACT1 includes a first active layer 131 and a second active layer 132 in order of closeness to the first gate electrode G1. The mobility of the second active layer 132 is lower than that of the first active layer 131, and the first active pattern ACT1 has a multilayer structure having a difference in mobility.

The first active pattern ACT1 is composed of a first active layer 131 with high mobility and a second active layer 132 with normal mobility. A main channel is created in the first active layer 131 with high mobility, the region of the first active layer 131 overlapping the first gate electrode G1 is defined as the main channel, and rapid carrier movement is possible in the channel due to high mobility of the first active layer 131.

Also, the first active layer 131 with high mobility and the second active layer 132 with normal mobility are joined, and an interface between the active layers having a difference in mobility is created, which has the function of reducing light sensitivity of the first active pattern ACT1.

If the active pattern is composed of a single high-mobility active layer to improve mobility, there is a strong tendency for threshold voltage to shift in the negative direction, as shown in Table 1 below. Therefore, reliability of the transistor cannot be obtained with the single high-mobility active layer.

In addition, the transistor including the single high-mobility active layer can be found to exhibit high light sensitivity, as shown by the fact that the threshold voltage value changes significantly even with a small amount of light in the negative bias thermal illumination stress (NBTIS) experiment, which tests the transistor by increasing the light intensity under a negative bias voltage and heat.

TABLE 1

| | Number of layers (mobility) | | |
|---|---|---|---|
| | | | Two layers |
| | Single layer | Single layer | (High mobility/ |
| | (Normal mobility) | (High mobility) | normal mobility) |
| Initial threshold | 0.0 | −19.4 | 0.5 |
| voltage (V) | | | |
| Mobility | 9.0 | 32.2 | 18.1 |
| (cm²/Vs) | | | |

Accordingly, the light emitting display device according to an embodiment of the present disclosure is configured to have a multilayer structure including active layers having differences in mobility at least for transistors, thereby preventing a tendency for a negative shift in threshold voltage and preventing a problem in which the threshold voltage changes sensitively even to weak light in a structure of an active layer with high mobility. The experiment in Table 1 shows that, when two active layers having a difference in mobility are applied, the threshold voltage change is small, optical reliability is ensured, and at least a certain level of mobility is obtained.

The second transistor P2_T provided in the second area includes a second active pattern ACT2 and a second gate electrode G2 overlapping the second active pattern ACT2 on the substrate 110. Also, the second transistor P2_T may include third and fourth source/drain electrodes SD21, SD22 spaced apart from each other at both sides with the second gate electrode G2 therebetween.

The second active pattern ACT2 of the second transistor P2_T disposed in the second area SA having the camera or sensor has higher average mobility than the first active pattern ACT1. This is because high luminance driving is required in the second transistor P2_T of the second area SA compared to the first transistor P1_T of the first area BA.

To this end, the second active pattern ACT2 of the second transistor P2_T has multiple interfaces having differences in mobility.

The second active pattern ACT2 includes a first active layer 131, a second active layer 132, and a third active layer 133 in order of closeness to the second gate electrode. The third active layer 133 may have higher mobility than the second active layer 132, and an edge of the third active layer 133 on a plane may be identical to or adjacent to an edge of the second gate electrode G2.

The first and third active layers 131, 133 have higher mobility than the second active layer 132, and the second active pattern ACT2 is configured such that the first to third active layers 131, 132, 133 are disposed in order of high mobility, normal mobility, and high mobility in order of increasing distance from the second gate electrode G2.

The second transistor P2_T of the second area SA includes the third active layer 133 beneath the second active layer 132, and the second active pattern ACT2 exhibits mobility closer to the mobility of the third active layer 133 than the mobility corresponding to the average mobility value of the first and second active layers 131, 132, so that the mobility of the second active pattern ACT2 is greater than that of the first active pattern ACT1 of the first transistor P1_T. Therefore, the second transistor P2_T is capable of carrier generation and transport corresponding to high luminance characteristics of the second area SA.

When source/drain regions are defined at both sides of the second gate electrode G2 by doping both sides with impurities using the second gate electrode G2 as a mask in the second active pattern ACT2, the region overlapping the second gate electrode G2 between the source/drain regions may function as a channel.

Referring to FIG. 4, for the channel in the second active pattern ACT2, the distance of the second active pattern ACT2 overlapping the second gate electrode G2 between the third and fourth source/drain electrodes SD21, SD22 may be defined as a channel length L, and a channel width W may be defined in a direction intersecting the channel length L. In FIG. 4, the channel width W is along the Y-axis direction and the channel length L is along the X-axis direction.

For the second active pattern ACT2, a main channel may be formed in the first and third active layers 131, 133 with high mobility. Also, a path for current to flow is generated at the interface between the first active layer 131 and the second active layer 132 and at the interface between the second active layer 132 and the third active layer 133, having differences in mobility, and the channel area increases and the quantity of carriers generated increases. Moreover, compared to a structure having a single interface between active layers having a difference in mobility, the structure having multiple interfaces between active layers having differences in mobility in a plurality of layers has an effect of increasing mobility due to an increase in the channel area.

When voltage is applied to the gate electrode in the transistor, carriers are generated in the channel between the source/drain regions of the active layer. In the second transistor P2_T of FIG. 4, the second active pattern ACT2 have two interfaces between active layers 131/132, 132/133 having differences in mobility in the vertical direction (Z-axis direction), and a current path is created through the two interfaces and the increased electrons move as carriers, thereby increasing the mobility of the second transistor P2_T.

Meanwhile, the second active pattern ACT2 is configured such that the third active layer 133 is disposed to overlap the second gate electrode G2, and the third active layer 133 may be formed in a size corresponding to the channel. Accordingly, the edge of the third active layer 133 may be identical to or nearly identical to the edge of the second gate electrode G2. While the first and second active layers 131, 132 have source/drain regions doped with impurities in the regions located at both sides of the second gate electrode G2, the third active layer 133 may have only a channel region and may not have source/drain regions doped with impurities.

In the second active pattern ACT2, the first and third active layers 131, 133 with high mobility may each have a region, functioning as a channel, overlapping the second gate electrode G2. In the second active pattern ACT, two active layer interfaces are created at the interface between the first active layer 131 and the second active layer 132 and at the interface between the third active layer 133 and the second active layer 132, having differences in mobility, and a current path is created through the two active layer interfaces having differences in mobility and the increased electrons move as carriers, so that dual channels are applied, greatly increasing the mobility.

In embodiments of the present disclosure, the mobility of the first and third active layers 131, 133 with high mobility may be 15 cm²/Vs or more, and the mobility of the second active layer 132 with normal mobility may be 14 cm²/Vs or less.

A 123% increase in mobility was experimentally confirmed in the stack structure of first active layer with high mobility/second active layer with normal mobility/third active layer with high mobility compared to the stack structure of first active layer with high mobility/second active layer with normal mobility. The experiment was performed under the condition that the mobility of the first and third active layers 131, 133 was set to 20 cm²/Vs and the mobility of the second active layer 132 with normal mobility was set to 10 cm²/Vs.

In a light emitting display device according to an embodiment of the present disclosure, the first active layer 131 and the third active layer 133 may include at least one of SnO (Sn-oxide), FIZO (Fe—In—Zn-oxide), or ZnO (Zn-oxide).

In a light emitting display device according to another embodiment of the present disclosure, the first to third active layers 131, 132, 133 each include IGZO (In—Ga—Zn-oxide), the first and third active layers 131, 133 may have an indium content greater than a gallium content, and the second active layer 132 may have an indium content less than or equal to a gallium content.

Meanwhile, the first and second transistors P1_T, P2_T include a first light blocking pattern BS1 and a second light blocking pattern BS2 under the first active pattern ACT1 and the second active pattern ACT2, respectively, so as to prevent influence of light coming from the lower side of the substrate 110.

As shown in FIG. 4, the vertical distance between the second light blocking pattern BS2 and the second active pattern ACT2 in the second transistor P2_T is a first distance D1, which is shorter than a second distance D2, which is the vertical distance between the first light blocking pattern BS1 and the first active pattern ACT1 in the first transistor P1_T. This is because the third active layer 133 is disposed beneath the second active layer 132, thereby reducing the vertical distance between the second light blocking pattern BS2 and the second active pattern ACT2 overlapping the second gate electrode G2.

The first and second transistors P1_T, P2_T may be manufactured through the same process. The first and second transistors P1_T, P2_T are configured such that the first and second light blocking patterns BS1, BS2 are located on the same layer, the first and second active layers 131, 132 of the first and second active patterns ACT1, ACT2 are located on the same layer, the first and second gate electrodes G1, G2 are located on the same layer, and the first to fourth source/drain electrodes SD11, SD12, SD21, SD22 are located on the same layer.

A first insulating film 121 between the first and second light blocking patterns BS1, BS2 and the first and second active patterns ACT1, ACT2 may be formed of, for example, an inorganic insulating film. The inorganic insulating film may include at least one inorganic insulating film selected from among, for example, a silicon oxide film (SiOx), a silicon nitride film (SiNx), and a silicon oxynitride film (SiOxNy), or may include a multilayer film in which the inorganic insulating films described above are stacked. When the first and second active patterns ACT1, ACT2 are made of multilayer oxide semiconductors, the first insulating film 121 may be made of a silicon oxide film in order to prevent hydrogen influence on the first and second active patterns ACT1, ACT2 by the first insulating film 121.

The first insulating film 121 may function as a buffer layer for the first and second active patterns ACT1, ACT2.

In addition, the first and second light blocking patterns BS1, BS2 may be formed of a conductive metal material, and specifically, the conductive metal material may include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The first and second light blocking patterns BS1, BS2 may also include a hydrogen capturing metal to prevent hydrogen penetration or diffusion into the first and second active patterns ACT1, ACT2.

A second insulating film 123 may be disposed between the first and second active patterns ACT1, ACT2 and the first and second gate electrodes G1, G2. The second insulating film 123 may be an inorganic insulating film. When the first and second active patterns ACT1, ACT2 are made of multilayer oxide semiconductors, the second insulating film 123 may be made of a silicon oxide film in order to prevent hydrogen influence on the first and second active patterns ACT1, ACT2 by the second insulating film 123 closest to the first and second active patterns ACT1, ACT2.

The second insulating film 123 may include multiple layers. When including multiple layers, the insulating film closest to the first and second active patterns ACT1, ACT2 may be formed of a silicon oxide film, and the insulating film thereon may be formed of a different type of inorganic film.

The first and second gate electrodes G1, G2 may be formed of a conductive metal material, and specifically, the conductive metal material may include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The first and second gate electrodes G1, G2 may also include a hydrogen capturing metal to prevent hydrogen penetration or diffusion into the first and second active patterns ACT1, ACT2.

In addition, a third insulating film 124 may be provided between the first and second gate electrodes G1, G2 and the first to fourth source/drain electrodes SD11, SD12, SD21, SD22.

The third insulating film 123 may be formed of, for example, an inorganic insulating film. The inorganic insulating film may include at least one inorganic insulating film selected from among, for example, a silicon oxide film (SiOx), a silicon nitride film (SiNx), and a silicon oxynitride film (SiOxNy), or may include a multilayer film in which the inorganic insulating films described above are stacked.

The first to fourth source/drain electrodes SD11, SD12, SD21, SD22 may be made of a conductive metal material, and specifically, the conductive metal material may include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

Meanwhile, the first and second transistors P1_T, P2_T of the illustrated example show that the gate electrodes G1, G2 and the source/drain electrodes SD11/SD12, SD21/SD22 are located on different layers, but embodiments of the present disclosure are not limited thereto. In some cases, the gate electrodes G1, G2 and the source/drain electrodes SD11/SD12, SD21/SD22 may be located on the same layer, forming the first and second transistors P1_T, P2_T in a coplanar structure.

Meanwhile, in the light emitting display device according to an embodiment of the present disclosure, the second transistor P2_T includes the third active layer 133 beneath the second active layer 132, so that the vertical distance between the second light blocking pattern BS2 and the second active pattern ACT2, which is set to a first distance D1, is less than a second distance D2 between the first light blocking pattern BS1 and the first active pattern ACT1 in the first transistor P1_T. Capacitance is inversely proportional to the vertical distance between two electrodes, and capacitance C_{BUF} of the buffer layer generated between the second active pattern ACT2 and the second light blocking pattern BS2 in the second transistor P2_T may be greater than capacitance C_{BUF} of the buffer layer in the first transistor P1_T. In FIG. 4, the first insulating film 121 is used as a common buffer layer in the first and second transistors P1_T, P2_T, but the second transistor P2_T is configured such that a recess 121R is formed in an upper surface USS of the first insulating film 121 and the third active layer 133, which is the lowest layer of the second active pattern ACT2, is provided at a lower position compared to the first active pattern ACT1, thereby reducing the thickness difference between the first active pattern ACT1 and the second active pattern ACT2 formed through the same process and the vertical distance difference between the first and second active patterns and the first and second light blocking patterns BS1, BS2 located thereunder.

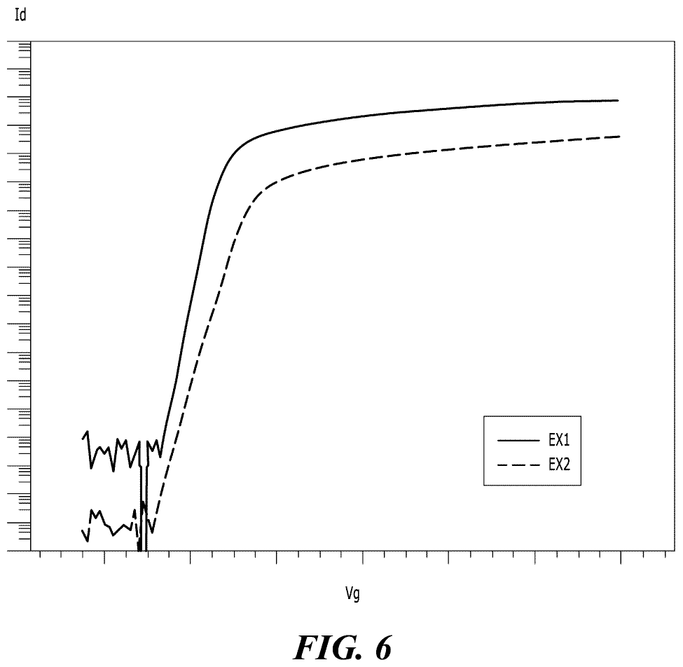

In the second experimental example of FIG. 6, the second transistor P2_T is able to increase the S-factor value proportional to the capacitance C_{BUF} value of the buffer layer, obtaining a range of change in Vgs until Ids are saturated when the second transistor P2_T functions as a driving transistor, thereby enabling various gradation expressions.

In the first transistor P1_T and the second transistor P2_T, the first insulating film 121 functions as a buffer layer, and the second insulating film 123 functions as a gate insulating film. In the first transistor P1_T and the second transistor P2_T, the second insulating film 123 having the same thickness is applied, and the third active layer 133 is selectively applied to the second transistor P2_T, so that the vertical distance of the first insulating film 121 that functions as a buffer layer is reduced only in the second transistor P2_T. Accordingly, the S-factor of the second transistor P2_T may increase compared to the first transistor P1_T, thereby providing the effect of enriching gradation expression. In particular, the second transistor P2_T has a structure having high mobility, including the first and third active layers 131, 133 with high mobility, and thus has the advantage of sufficiently enabling low-gradation expression by obtaining a constant change range of Ids at low Vgs.

Meanwhile, the first light blocking pattern BS1 may be connected to the first source/drain electrode SD11 or the second source/drain electrode SD12 that overlaps for potential stabilization, and the second light blocking pattern BS2 may be connected to the third or fourth source/drain electrode SD21, SD22 that overlaps for potential stabilization.

Referring to FIG. 5, a case will be described where the second active pattern ACT2 of the second transistor P2_T is configured to include first to third active layers 131, 132, 133, and each of the first to third active layers 131, 132, 133 is made of an oxide semiconductor.

The first and third active layers 131, 133 with high mobility (HM) have a smaller energy band gap than the second active layer 132 with normal mobility (NM) corresponding to relatively low mobility. As shown in FIG. 4, in the second active pattern ACT2, the source/drain regions of the first active layer 131 are connected to the third and fourth source/drain electrodes SD21, SD22, and when voltage is applied through the second gate electrode G, a channel is generated in the region of the second active pattern ACT2 that overlaps the second gate electrode G between the source/drain regions. As such, the regions of the first and third active layers 131, 133 overlapping the second gate electrode G have high mobility, creating main channels, and in the second active pattern ACT2, a carrier concentration effect occurs at the interface between the second insulating film 123 and the first active layer 131 and at the interface between the second active layer 132 and the third active layer 133, channels are generated at multiple interfaces having differences in mobility, and carriers become abundant in the second active pattern ACT2. Accordingly, when voltage is applied to the second gate electrode G2, a Fermi energy level (Ef) is generated near the electron conduction energy level (Ec: conduction energy level) of the first and third active layers 131, 133 in the direction toward the second insulating film 123 functioning as a gate insulating film (O-GI), and a path for current to flow is generated in the second insulating film 123, the first active layer 131, the second active layer 132, and the third active layer 133. Since the electron conduction energy level of the first and third active layers 131, 133 is closer to the Fermi energy level, carriers are more intensively generated in the first and third active layers 131, 133 than in the second active layer 132, and electrons are efficiently transferred through the second insulating film 123 and the second active layer 132 adjacent to the first and third active layers 131, 133. Carriers are intensively generated at the interface between the third active layer 133 and the second active layer 132 and at the interface between the first active layer 131 and the second insulating film 123, and electron flow occurs at the electron conduction energy level of the first and third active layers 131, 133. Carriers are enriched in the second active pattern ACT2 due to the channel effect occurring at a plurality of multilayer interfaces, and the quantity of current may be increased by voltage application suitable for high current demand of the second area SA.

As shown in FIG. 5, the third active layer 133 of the second active pattern ACT23 is formed by filling the inside of a recess having a certain depth provided in the upper surface of the first insulating film 121. The second active pattern ACT2 may include the third active layer 133 corresponding to the length L of the channel located between the third and fourth source/drain electrodes SD21, SD22. Accordingly, the third active layer 133 is located to overlap the second gate electrode G2 and may have a smaller area than the first and second active layers 131, 132. The third active layer 133 is provided to increase the number of channels and increase mobility in the second transistor P2_T and may include only an intrinsic region. On the other hand, the first and second active layers 131, 132 may include source/drain regions doped with impurities in the regions connected to the third and fourth source/drain electrodes SD21, SD22. Specifically, the first and second active layers 131, 132 include an intrinsic region overlapping the second gate electrode G2 and conductive regions at both sides of the intrinsic region. In contrast, the third active layer 133 may only include an intrinsic region.

FIG. 6 is a graph showing the Ids-Vgs relationship in a structure with a difference in thickness between the light blocking pattern and the active layer in the driving transistor.

The first experimental example (EX1) shows an example of a driving transistor with a small S-factor, and the second experimental example (EX2) shows an example of a driving transistor with a large S-factor.

The S-factor is inversely proportional to the slope of the graph when observing a change in Ids depending on Vgs, and FIG. 6 shows that the S-factor value of the second experimental example (EX2) with a relatively small slope is large.

Referring to FIG. 6, the second experimental example (EX2) with a large S-factor value shows a gentle change in Ids depending on Vgs compared to the first experimental example (EX1), indicating that the extent of change of Ids is not large depending on a predetermined change in Vgs until saturation after the driving transistor is turned on. The second experimental example (EX2) does not have a rapid increase in Ids at low Vgs, enabling sufficient low-gradation expression.

As described above, the second transistor P2_T of the second area increased the capacitance of the buffer layer and increased the S-factor value by reducing the vertical distance D1 between the second light blocking pattern BS2 and the second active pattern ACT2.

Specifically, in the light emitting display device according to embodiments of the present disclosure, the second transistor P2_T of the second area having the camera or sensor is configured such that the second active pattern ACT2 includes a plurality of high-mobility active layers to increase mobility, but the vertical distance between the second light blocking pattern BS2 and the second active pattern ACT2 is reduced, confirming that the S-factor increases and rich gradation expression including low gradation is possible.

Specifically, when the second transistor P2_T described above is provided as a driving transistor of the second area, a gentle change in Ids is obtained at low Vgs, preventing a rapid change in Ids depending on a change in Vgs even if the second active pattern has high mobility, thereby enabling sufficient gradation expression.

More specifically, the light emitting display device according to embodiments of the present disclosure includes both a high-mobility active layer and a low-mobility active layer in the first area BA that does not have a camera or sensor and the second area SA that includes a camera or sensor, thereby obtaining certain mobility of the transistor and also preventing a shift in threshold voltage in the negative direction as well as light sensitivity of a single high-mobility active layer structure.

In addition, the transistor of the second area SA further includes a high-mobility active layer compared to the first area BA, so that high mobility characteristics of the second area SA are further obtained, and a camera or sensor is provided and transmissive portions are also provided, achieving a low-resolution arrangement density, thereby responding to situations where high voltage application and high current driving are required compared to the transistor of the first area.

The transistor of the second area SA also includes the third active layer with high mobility at a lower position of the second active pattern, reducing the vertical distance from the second light blocking pattern BS2, thereby increasing the S-factor and enabling rich gradation expression including low gradation.

In the first transistor P1_T and the second transistor P2_T, the first insulating film 121 functions as a buffer layer and the second insulating film 123 functions as a gate insulating film. In the first transistors P1_T and the second transistor P2_T, the second insulating film 123 having the same thickness is applied, and the third active layer 133 is selectively applied to the second transistor P2_T, so that the vertical distance of the first insulating film 121 that functions as a buffer layer is reduced only in the second transistor P2_T. Accordingly, the S-factor of the second transistor P2_T increases compared to the first transistor P1_T, thereby providing the effect of enriching gradation expression. In particular, the second transistor P2_T has a structure having high mobility, including the first and third active layers 131, 133 with high mobility, and thus has the advantage of sufficiently enabling low-gradation expression by obtaining a constant change range of Ids at low Vgs.

Meanwhile, the transistors P1_T, P2_T of the first and second areas of the light emitting display device according to an embodiment of the present disclosure may be formed through the same process.

The process of manufacturing the first and second transistors is described below.

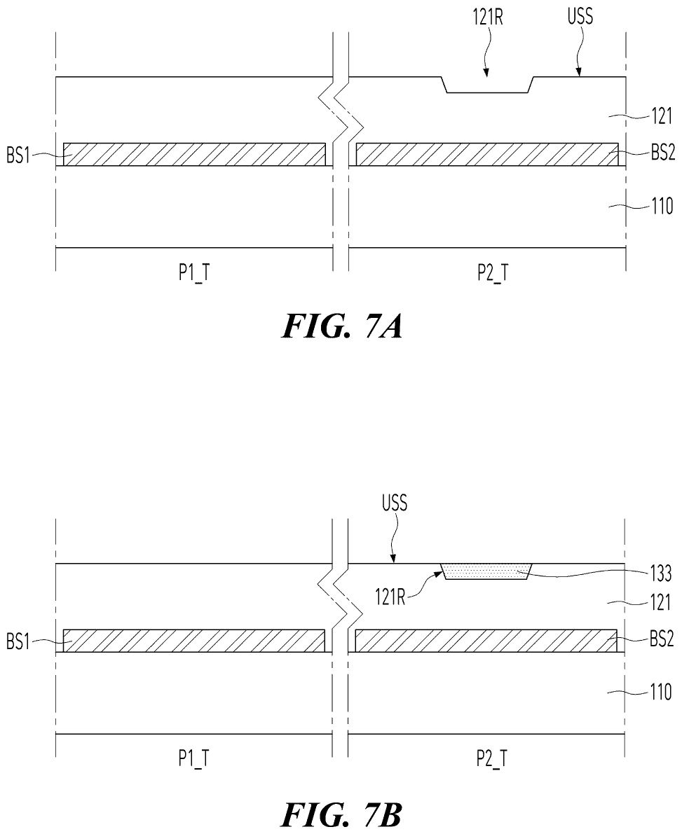

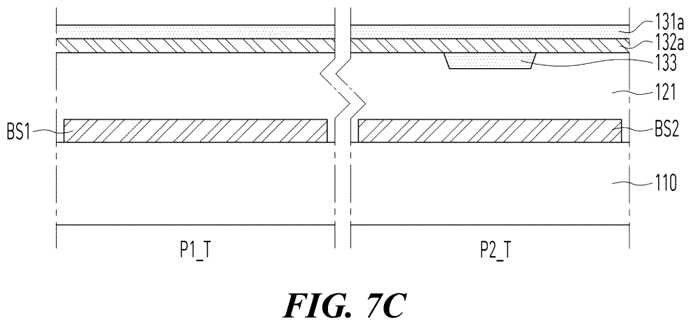

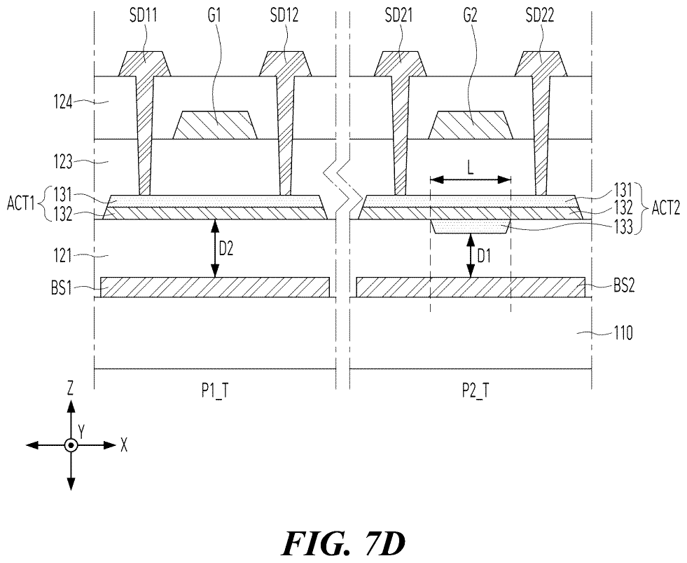

FIGS. 7A to 7D are cross-sectional views showing the process of manufacturing a light emitting display device according to an embodiment of the present disclosure.

As shown in FIG. 7A, first and second light blocking patterns BS1, BS2 are formed on the substrate 110 using a conductive metal material in the first transistor P1_T region of the first area BA (FIG. 3) and the second transistor P2_T region of the second area SA, respectively.

The substrate 110 shown in FIG. 7A, etc., is illustrated in the form of a single layer, but may further include a single or multiple buffer layers.

The first and second light blocking patterns BS1, BS2 may further include a hydrogen capturing metal to prevent hydrogen diffusion into the active patterns when adjacent active patterns are made of oxide semiconductors.

Next, a first insulating film 121 is disposed on the substrate 110 including the first and second light blocking patterns BS1, BS2. The first insulating film 121 may function as a buffer layer for first and second active patterns ACT1, ACT2 that are subsequently formed.

A recess 121R is selectively formed in the second transistor P2_T region of the second area SA by removing a portion of the upper surface USS of the first insulating film 121 by a predetermined thickness.

The recess 121R is formed at a depth less than the entire thickness of the first insulating film 121, and may have a shape having a width and length corresponding to the channel of the second active pattern that is subsequently formed. The lower surface of the recess 121R is spaced apart from the upper surface of the second light blocking pattern BS2 by a first distance D1.

Next, a third active material layer is formed by front side deposition using a high-mobility oxide semiconductor on the first insulating film 121 with filling the recess 121R. The upper surface USS of the first insulating film 121 is exposed by a planarization process, thus a third active layer 133 is provided in the recess 121R, as shown in FIG. 7B.

Here, the upper surface USS of the first insulating film 121 is exposed around the third active layer 133 loaded in the recess 121R.

Next, as shown in FIG. 7C, a second active material layer 132a using a normal-mobility oxide semiconductor and a first active material layer 131a using a high-mobility oxide semiconductor are sequentially formed.

Next, as shown in FIG. 7D, the first active material layer 131a and the second active material layer 132a are patterned with the same mask, forming a first active pattern ACT1 and a second active pattern ACT2 corresponding to the first transistor P1_T region of the first area BA (FIG. 3) and the second transistor P2_T region of the second area SA, respectively.

Here, the second active pattern ACT2 includes the first to third active layers 131, 132, 133, and has a shape in which the first and second active layers 131, 132 protrude to both sides than the third active layer 133 and which overlaps the second light blocking pattern BS2.

The first active pattern ACT1 includes the first and second active layers 131, 132. The first and second active layers 131, 132 may have a shape overlapping the first light blocking pattern BS1.

Next, a second insulating film 123 made of an inorganic insulating material is disposed to cover the first and second active patterns ACT1, ACT2. The second insulating film 123 may function as a gate insulating film.

Next, a first gate electrode G1 and a second gate electrode G2 are respectively disposed in the first transistor P1_T region of the first area BA (FIG. 3) and the second transistor P2_T region of the second area SA on the second insulating film 123.

By performing an impurity doping process on the first and second active patterns ACT1, ACT2 using the first and second gate electrodes G1, G2 as a mask, source/drain regions may be defined in the first and second active patterns ACT1, ACT2. The source/drain regions may be commonly defined in the first and second active patterns ACT1, ACT2 by doping both sides of the first and second active layers 131, 132 with impurities.

Next, a third insulating film 124 is formed on the second insulating film 123 on which the first and second gate electrodes G1, G2 are disposed.

Contact holes that expose portions of the upper surface at both sides of each of the first active pattern ACT1 and the second active pattern ACT2 are formed by selectively removing the third insulating film 124 and the second insulating film 123. Next, patterning is performed to fill the contact holes with a conductive metal material, forming first and second source/drain electrodes SD12, SD12 connected to the first active pattern ACT1 through the contact holes and third and fourth source/drain electrodes SD21, SD22 connected to the second active pattern ACT2 through the contact holes.

In the light emitting display device according to embodiments of the present disclosure, the first transistor P1_T provided in the first area and the second transistor P2_T provided in the second area are formed through the same process. Also, the third active layer 133 of the second transistor P2_T, corresponding to a difference between the first and second transistors P1_T, P2_T, is formed by filling the inside of a recess 121R provided in the first insulating film 123, making it easy to control the depth, width, and length thereof, thereby facilitating control of the mobility required for the second transistor P2_T and control of the S-factor.

Meanwhile, the second area SA including a camera or sensor may have high current and high luminance characteristics using the transistors P2_T, P1_T described above as driving transistors, and by adjusting the recess 121R in the first insulating film, the S-factor may be increased, thus increasing mobility, thereby enriching gradation expression even in a state where high current driving is possible.

Each sub-pixel in the first and second areas BA, SA may include a switching transistor or a transistor having a different shape from the illustrated transistor in addition to the driving transistor.

Below is a description of a light emitting display device including different transistors in sub-pixels with reference to the drawing.

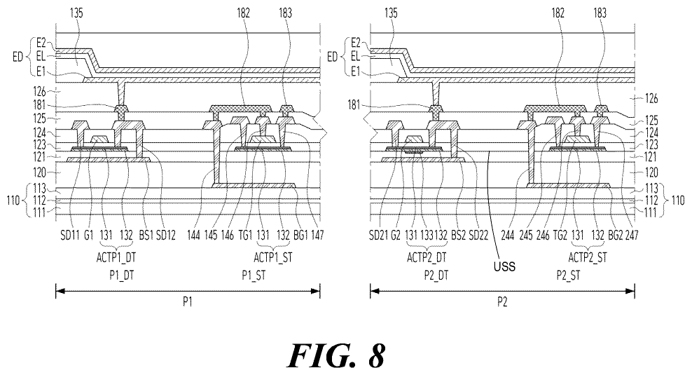

FIG. 8 is a cross-sectional view showing a light emitting display device according to an embodiment of the present disclosure.

As shown in FIG. 8, the driving transistor P1_DT provided in the first pixel P1 of the first area includes a first active pattern ACTP1_DT and a first gate electrode G1 overlapping the first active pattern ACTP1_DT on the substrate 110.

Also, in the driving transistor P1_DT provided in the first pixel P1, the first active pattern ACTP1_DT includes a first active layer 131 with high mobility at a position closer to the first gate electrode G1 and a second active layer 132 with normal mobility beneath the first active layer 131, so that a channel is generated at an interface having a difference in mobility, thus obtaining high mobility characteristics and also preventing a shift of threshold voltage in the negative direction as well as light sensitivity, thereby obtaining reliability of the transistor.

The driving transistor P1_DT provided in the first pixel P1 includes first and second source/drain electrodes SD11, SD12 spaced apart from each other at both sides with the first gate electrode G1 therebetween.

The driving transistor P1_DT provided in the first pixel P1 includes a first light blocking pattern BS1 provided under the first active pattern ACTP1_DT, so that external light may be prevented from entering the bottom of the first active pattern ACT1.

Meanwhile, the first pixel P1 further includes a switching transistor P1_ST in addition to the driving transistor P1_DT, obtaining switching characteristics for high speed driving in sub-pixels.

The switching transistor P1_ST provided in the first pixel PI of the first area includes an active pattern ACTP1_ST having the same structure as the first active pattern ACTP1_DT described above and a top gate electrode TG1 overlapping the active pattern ACTP1_ST on the substrate 110.

Also, in the switching transistor P1_ST provided in the first pixel P1, the active pattern ACTP1_ST includes a first active layer 131 with high mobility at a position closer to the top gate electrode TG1 and a second active layer 132 with normal mobility beneath the first active layer 131, so that a channel is generated at an interface having a difference in mobility, thus obtaining high mobility characteristics and also preventing a shift of threshold voltage in the negative direction as well as light sensitivity, thereby obtaining reliability of the transistor.

Furthermore, the switching transistor P1_ST provided in the first pixel P1 includes source/drain electrodes 145, 147 spaced apart from each other at both sides with the gate electrode TG1 therebetween.

The switching transistor P1_ST provided in the first pixel P1 has a light blocking pattern BG1 provided under the active pattern ACTP1_ST, so that external light may be prevented from entering the bottom of the active pattern ACTP1_ST.

In the switching transistor P1_ST provided in the first pixel P1, the light blocking pattern BG1 has the same potential as the top gate electrode TG1, and the light blocking pattern BG1 may be used as a bottom gate electrode. To this end, a first connection pattern 144 provided on the same layer as the source/drain electrodes 145, 147 and connected to the light blocking pattern BG1, a second connection pattern 146 connected to the top gate electrode TG1, and a third connection pattern 182 provided over the first and second connection patterns 144, 146 and configured to connect the first and second connection patterns 144, 146 may be included.

In one embodiment of the present disclosure, the switching transistor P1_ST provided in the first pixel P1 enables high speed driving due to use of dual gates, and arrangement is possible by reducing the plane area because overlapping dual gates are provided. Also, high speed operation is possible due to supply of dual gate voltages. High speed operation is possible in a small size due to potential stabilization of the first light blocking metal BG1 and application of dual gate structures of the switching transistor P1_ST.

In the first pixel P1, one 147 of the source/drain electrodes of the switching transistor P1_ST may be connected to a data line 183.

Also, the driving transistor P1_DT provided in the first pixel P1 may be connected to a fourth connection electrode 181 and linked to the anode E1 of the light emitting device ED.

A driving transistor P2_DT provided in the second pixel P2 of the second area includes a second active pattern ACTP2_DT and a second gate electrode G2 overlapping the second active pattern ACTP2_DT on the substrate 110. Also, the driving transistor P2_DT of the second pixel P2 may include third and fourth source/drain electrodes SD21, SD22 spaced apart from each other at both sides with the second gate electrode G2 therebetween.

The second active pattern ACTP2_DT of the driving transistor P2_DT of the second pixel disposed in the second area SA having the camera or sensor has higher average mobility than the first active pattern ACTP1_DT. To this end, the second active pattern ACTP2_DT of the driving transistor P2_DT of the second pixel P2 has multiple interfaces having differences in mobility.

The second active pattern ACTP2_DT includes a first active layer 131, a second active layer 132, and a third active layer 133 in order of closeness to the second gate electrode G2. Here, the third active layer 133 may have higher mobility than the second active layer 132, and an edge of the third active layer 133 on a plane may be identical to or adjacent to an edge of the second gate electrode G2.

The first and third active layers 131, 133 have higher mobility than the second active layer 132, and the first to third active layers 131, 132, 133 in the second active pattern ACT2 are disposed in order of high mobility, normal mobility, and high mobility in order of increasing distance from the second gate electrode G2.

The driving transistor P2_DT of the second area SA includes the third active layer 133 beneath the second active layer 132, and the second active pattern ACTP2_DT exhibits mobility closer to the mobility of the third active layer 133 than the mobility corresponding to the average mobility value of the first and second active layers 131, 132, so that the mobility of the second active pattern ACT2 is greater than that of the first active pattern ACT1 of the driving transistor P1_DT of the first pixel. Therefore, the driving transistor P2_DT of the second pixel is capable of carrier generation and transport corresponding to high luminance characteristics of the second area SA.

The second active pattern ACT2 may have a main channel formed in the first and third active layers 131, 133 with high mobility. In addition, a path for current to flow is generated at the interface between the first active layer 131 and the second active layer 132 and at the interface between the second active layer 132 and the third active layer 133, having differences in mobility, and the channel area increases and the quantity of carriers generated increases. Moreover, compared to a structure having a single interface between active layers having a difference in mobility, the structure having multiple interfaces between active layers having differences in mobility in a plurality of layers has an effect of increasing mobility due to an increase in the channel area.

When voltage is applied to the gate electrode in the transistor, carriers are generated in the channel between the source/drain regions of the active layer. In the driving transistor P2_DT of the second pixel, the second active pattern ACT2 has two interfaces between the active layers 131/132, 132/133 having differences in mobility in the vertical direction (Z-axis direction), and a current path is created through the two interfaces and the increased electrons move as carriers, thereby increasing the mobility of the driving transistor P2_DT of the second pixel.

Meanwhile, the second active pattern ACT2 is configured such that the third active layer 133 is disposed to overlap the second gate electrode G2, and the third active layer 133 may be formed in a size corresponding to the channel. Accordingly, the edge of the third active layer 133 may be identical to or nearly identical to the edge of the second gate electrode G2. While the first and second active layers 131, 132 have source/drain regions doped with impurities in the regions located at both sides of the second gate electrode G2, the third active layer 133 may have only a channel region and may not have source/drain regions doped with impurities.

The active pattern ACTP2_DT of the driving transistor of the second pixel has two active layer interfaces between the first active layer 131 and the second active layer 132 and between the third active layer 133 and the second active layer 132, having differences in mobility, and a current path is generated through the two active layer interfaces having differences in mobility and the increased electrons move as carriers, so that dual channels are applied, greatly increasing the mobility.

In embodiments of the present disclosure, the mobility of the first and third active layers 131, 133 with high mobility may be 15 cm²/Vs or more, and the mobility of the second active layer 132 with normal mobility may be 14 cm²/Vs or less.

In a light emitting display device according to an embodiment of the present disclosure, the first active layer 131 and the third active layer 133 may include at least one of SnO (Sn-oxide), FIZO (Fe—In—Zn-oxide), or ZnO (Zn-oxide).

In a light emitting display device according to another embodiment of the present disclosure, the first to third active layers 131, 132, 133 each include IGZO (In—Ga—Zn-oxide), the first and third active layers 131, 133 may have an indium content greater than a gallium content, and the second active layer 132 may have an indium content less than or equal to a gallium content.

Meanwhile, the driving transistor P2_DT of the second pixel may include a second light blocking pattern BS2 under the second active pattern ACT2, preventing influence of light coming from the lower side of the substrate 110.

In addition, the second pixel P2 may further include a switching transistor P2_ST in addition to the driving transistor P2_DT, obtaining switching characteristics for high speed driving in sub-pixels. The switching transistor P2_ST of the second pixel P2 may have the same structure as the switching transistor P1_ST of the first pixel PI described above.

Below, components other than the transistors are described.

The substrate 110 may include a base 111 and first and second buffer layers 112, 113.

The base 111 may be formed of a flexible plastic material and thus may have flexibility.

For example, the base 111 may be composed of first and second organic films overlapping each other with an inorganic interlayer insulating film therebetween. The first and second organic films may include different organic films of the same or different types, such as PET (polyethylene terephthalate), polyimide, etc. In some cases, an adhesive film such as a pressure sensitive adhesive (PSA) may be interposed between the first and second organic films.

As another example, the base 111 may include a thin glass material having flexibility.

The base 111 serves to support and protect the components of the display device 1000 disposed thereon.

A plurality of insulating films 112, 113, 120, 121, 123, 124, 125, 126 is stacked and disposed on the active area AA and the non-active area NA (FIG. 1) of the base 111, so that the electrodes B1, G1, SD11/SD12, electrodes B2, G2, SD21/SD22, electrodes BG1, TG1, 145, 147, and electrodes BG2, TG2, 245, 247 constituting the driving transistors P1_DT, P2_DT and the switching transistors P1_ST, P2_DT of the first and second pixels may be insulated from each other.

The first buffer layer 112 and the second buffer layer 113 are made of an inorganic insulating material and are disposed on the active area AA and the non-active area NA of the base 111. The first buffer layer 112 and the second buffer layer 113 are disposed on the base 111 to protect structures located on the base 111 from water penetrating through the base 111 and to achieve surface planarization of the base 111.

The first buffer layer 112 is disposed up to the edge of the base 111 to prevent water penetration from the edge of the base 111. The first buffer layer 112 may be made of a plurality of inorganic films when transistors of other types are further included in addition to the transistors shown on the base 111, and may be used as an interlayer insulating film or gate insulating film of other transistors.

For example, the first buffer layer 112 may include at least one inorganic film selected from among a silicon oxide film (SiOx), a silicon nitride film (SiNx), and a silicon oxynitride film (SiOxNy), or may include a multilayer film in which the inorganic films described above are stacked.

The second buffer layer 113 may be disposed on the first buffer layer 112. For example, some of transistors included in sub-pixels may include a polysilicon semiconductor layer (not shown), and a second insulating film 122 may be located under the polysilicon semiconductor layer. The second insulating film 122 may include an inorganic film, for example, a silicon oxide film (SiOx), a silicon nitride film (SiNx), or a multilayer film thereof. In some cases, the second buffer layer 113 may be used as a gate insulating film of a transistor including a polysilicon semiconductor layer.

Light blocking patterns BG1, BG2 may be provided using a conductive metal material on the second buffer layer 113. Specifically, the conductive metal material may include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The light blocking pattern BG1, BG2 may form any one electrode of a storage capacitor included in a sub-pixel.

A third buffer layer 120 may be disposed on the second buffer layer 113 on which the light blocking patterns BG1, BG2 are provided. The third buffer layer 120 may function as an insulator for the storage capacitor of each sub-pixel. Alternatively, the third buffer layer 120 may function as an interlayer insulating film of a transistor including a polysilicon semiconductor layer.

The third buffer layer 120 may include an inorganic material. The inorganic material may include, for example, a silicon nitride film (SiNx).

On the third buffer layer 120, first and second light blocking patterns B1, B2 are respectively disposed in the first pixel P1 of the first area and the second pixel P2 of the second area using a conductive metal material. Specifically, the conductive metal material may include at least one selected from among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The first and second light blocking patterns B1, B2 may be located on the same layer as the first electrode and the second electrode of the storage capacitor, respectively. The first and second light blocking patterns B1, B2 may be provided in the form of a single layer or may have a stack structure of multiple different metal material layers.

A first insulating film 121 may be disposed on the third buffer layer 120 provided with the first and second light blocking patterns B1, B2. The first insulating film 121 is located beneath active patterns ACTP1_DT, ACTP1_ST, ACTP2_DT, ACTP2_ST and may function as a buffer layer. The first insulating film 121 may serve to achieve surface planarization of the area where active patterns ACTP1_DT, ACTP1_ST, ACTP2_DT, ACTP2_ST disposed thereon are formed.

The first insulating film 121 may include an inorganic material. The inorganic material may include, for example, a silicon oxide film (SiOx) or a multilayer film of stacked inorganic films.

On the first insulating film 121, a first active pattern ACTP1_DT of a driving transistor and an active pattern ACTP1_ST of a switching transistor in the first pixel P1, and a second active pattern ACTP2_DT of a driving transistor and an active pattern ACTP2_ST of a switching transistor in the second pixel P2 are disposed. The first active pattern ACTP1_DT of the driving transistor and the active pattern ACTP1_ST of the switching transistor in the first pixel P1, and the second active pattern ACTP2_DT of the driving transistor and the active pattern ACTP2_ST of the switching transistor in the second pixel P2 each include multilayer oxide semiconductors.

The second active pattern ACTP2_DT of the driving transistor in the second pixel includes a third active layer 133 with high mobility formed by filling the inside of a recess 121R (FIG. 7A) having a certain depth provided in the upper surface of the first insulating film 121, a second active layer 132 with normal mobility located on the third active layer 133 and the first insulating film 121 around the third active layer 133, and a first active layer 131 with high mobility.

The first active pattern ACTP1_DT of the driving transistor and the active pattern ACTP1_ST of the switching transistor in the first pixel P1 and the active pattern ACTP2_ST of the switching transistor in the second pixel P2 are formed by disposing the second active layer 132 with normal mobility and the first active layer 131 with high mobility on the upper surface of the first insulating film 121 without the third active layer 133 described above.

The oxide semiconductor material may be formed of a combination of at least one metal selected from among zinc (Zn), indium (In), gallium (Ga), tin (Sn), and titanium (Ti) and an oxide. In some cases, the mobility may be increased by further adding a highly conductive metal, such as tin (Sn), iron (Fe), etc., to the oxide semiconductor material, or the mobility may be adjusted by changing the composition ratio of metal combined with oxygen.

More specifically, the first active layer 131 and the third active layer 133 may be formed of high-mobility oxide semiconductors, and the second active layer 132 may be formed of a normal-mobility oxide semiconductor. Examples of the oxide semiconductor material constituting the first to third active layers 131, 132, 133 may include a tin compound (SnO), zinc oxide (ZnO), zinc-tin oxide (ZTO), iron-indium-zinc oxide (FIZO), zinc-indium oxide (ZIO), indium oxide (InO), titanium oxide (TiO), indium-gallium-zinc oxide (IGZO), indium-zinc-tin oxide (IZTO), and the like. High mobility and normal mobility may be varied by adjusting the composition ratio of metal included in the oxide semiconductor.

Each active pattern ACTP1_DT, ACTP1_ST, ACTP2_DT, ACTP2_ST has a multilayer structure including the active layer 131 with high mobility, thereby obtaining at least a certain level of mobility and also preventing a shift in threshold voltage and improving light sensitivity.

In addition, the second active pattern ACTP2_DT included in the driving transistor of the second area where the camera or sensor is disposed has a multilayer structure further including the third active layer 133 with high mobility beneath the second active layer 132 with normal mobility, thereby further increasing the mobility compared to the structure of two active layers, ultimately enabling operation as the driving transistor of the second pixel that requires relatively high current driving. Moreover, by positioning the third active layer 133 closer to the second light blocking pattern B2 and increasing the capacitance of the buffer layer, the S-factor is increased, and even in a structure having high mobility, Ids do not change rapidly but change gradually depending on a change in Vgs, so that gradation expression including low gradation may be enriched.

A second insulating film 123 is disposed to cover all the first active pattern ACTP1_DT of the driving transistor and the active pattern ACTP1_ST of the switching transistor in the first pixel P1 and the second active pattern ACTP2_DT of the driving transistor and the active pattern ACTP2_ST of the switching transistor in the second pixel P2. The second insulating film 123 may function as a gate insulating film.

Gate electrodes G1, TG1, G2, TG2 partially overlapping respective active patterns ACTP1_DT, ACTP1_ST, ACTP2_DT, ACTP2_ST are disposed on the second insulating film 123. The gate electrodes G1, TG1, G2, TG2 may include at least one selected from among an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The gate electrodes G1, TG1, G2, TG2 may be formed of a single layer or multiple layers.

A third insulating film 124 made of an inorganic insulating material is provided to cover the gate electrodes G1, TG1, G2, TG2. For example, the third insulating film may include a silicon oxide film (SiOx), a silicon nitride film (SiNx), or a multilayer film in which inorganic films are stacked.

When forming contact holes exposing both sides of each of the active patterns ACTP1_DT, ACTP1_ST, ACTP2_DT, ACTP2_ST, contact holes that expose portions of the first and second light blocking patterns BS1, BS2 of the driving transistors P1_DT, P2_DT, expose portions of the light blocking patterns BG1, BG2 of the switching transistors P1_ST, P2_ST, and expose portions of upper surfaces of the top gate electrodes TG1, TG2 of the switching transistors P1_ST, P2_ST are formed together.

The contact holes are filled with a conductive metal material, forming first and second source/drain electrodes SD11, SD12 and third and fourth source/drain electrodes SD21, SD22, which are respectively connected to both sides of the first and second active patterns ACTP1_DT, ACTP2_DT of the driving transistors P1_DT, P2_DT. The second source/drain electrode SD12 is connected not only to the first active pattern ACTP1_DT but also to the first light blocking pattern BS1 located thereunder. Also, the fourth source/drain electrode SD22 is connected not only to the second active pattern ACTP2_DT but also to the second light blocking pattern BS2 located thereunder.

The conductive metal material forming each of the source/drain electrodes SD11, SD12, SD21, SD22 may include at least one selected from among an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

For the switching transistor P1_ST, source/drain electrodes 145, 147 connected to both sides of the active pattern ACTP1_ST are provided, and for the switching transistor P2_ST, source/drain electrodes 245, 247 connected to both sides of the active pattern ACTP2_ST are provided. For the switching transistors P1_ST, P2_ST, first connection patterns 144, 244 connected to exposed portions of respective light blocking patterns BG1, BG2 are disposed, and second connection patterns 146, 246 connected to portions of the upper surfaces of respective top gate electrodes TG1, TG2 in the switching transistors P1_ST, P2_ST are disposed.

A fourth insulating film 125 covering the source/drain electrodes SD11, SD12, SD21, SD21, 145, 147, 245, 247 and the first and second connection patterns 144, 244, 146, 246 is provided, and contact holes exposing upper portions of the second and fourth source/drain electrodes SD12, SD22 of the driving transistors and contact holes exposing the first and second connection patterns 144, 244, 146, 246 of the switching transistors are formed together in the fourth insulating film 125.

The fourth insulating film 125 may be made of an inorganic insulating material or an organic insulating material. The inorganic insulating material may include, for example, a silicon oxide (SiOx) film, a silicon nitride (SiNx) film, or a multilayer film including stacked inorganic films. The organic insulating material may include at least one selected from among an acrylic resin, a phenolic resin, a polyimide resin, an unsaturated polyester resin, a polyamide resin, benzocyclobutene, a polyphenylene resin, and a polyphenylene sulfide resin.

A third connection pattern 182 configured to connect the first and second connection patterns 144/146, 244/246 of the switching transistors by filling the contact holes of the fourth insulating film 125 with a conductive metal material, and a data line 183 connected to some source/drain electrodes 147, 247 may be formed, and a fourth connection pattern 181 that is connected to the second and fourth source/drain electrodes SD12, SD22 of the driving transistors P1_DT, P2_DT may be provided.

The conductive metal material forming the third and fourth connection patterns 182, 181 and the data line 183 may include at least one selected from among an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

Also, a fifth insulating film 126 is provided on the fourth insulating film 125 including the third connection pattern 182, the fourth connection pattern 181, and the data line 183.

The fifth insulating film 126 is provided with a contact hole that exposes the fourth connection pattern 181 of the first pixel P1 and the second pixel P2.

The fifth insulating film 126 may be made of an organic insulating material to achieve planarization of the formation surface on which the light emitting device ED is to be formed. The organic insulating material may include at least one selected from among an acrylic resin, a phenolic resin, a polyimide resin, an unsaturated polyester resin, a polyamide resin, benzocyclobutene, a polyphenylene resin, and a polyphenylene sulfide resin.

The anode E1 of the light emitting device ED may be connected to the fourth connection pattern 181 through the contact hole of the fifth insulating film 126.

The light emitting device ED includes an anode E1, a cathode E2 opposite thereto, and an intermediate layer EL between the anode E1 and the cathode E2.

Either the anode E1 or the cathode E2 may include a reflective electrode, and the remaining one may include a transparent electrode or a reflective transparent electrode.

When the anode E1 includes a reflective electrode, the anode E1 may function to shield light from being incident on the first and second transistors T1, T2 at lower positions. The anode E1 may be formed of, for example, a stack structure of a first transparent electrode, a reflective electrode, and a second transparent electrode. The second transparent electrode, which is the uppermost electrode of the anode E1, may reduce the barrier for hole injection at the interface with the intermediate layer EL as a dielectric. Here, the first and second transparent electrodes may be transparent oxide electrodes formed of ITO, IZO, etc. The reflective electrode may include silver, a silver alloy such as APC (Ag—Pd—Cu), aluminum, or an aluminum alloy.

For example, the anode E1 may have a multilayer structure such as a stack structure of aluminum (Al) and titanium (Ti) (Ti/Al/Ti), a stack structure of aluminum (Al) and ITO (ITO/Al/ITO), an APC (Ag/Pd/Cu) alloy, and a stack structure of an APC alloy and ITO (ITO/APC/ITO), or a stack structure of silver (Ag) and molybdenum/titanium alloy (Ag/MoTi), or may have a monolayer structure made of any one material selected from among silver (Ag), aluminum (Al), molybdenum (Mo), gold (Au), magnesium (Mg), calcium (Ca), and barium (BA), or an alloy material of two or more thereof.

A pixel definition layer 135 is disposed to surround the edge of the anode E1, and an emissive portion may be defined in an open region of the pixel definition layer 135. The pixel definition layer 135 may extend to the non-active area NA and may have at least a partial overlapping region with the gate-in-panel GIP.

The pixel definition layer 135 may include an inorganic material or an organic material. The pixel definition layer 135 may include an opaque material (e.g., black) to prevent optical interference between adjacent sub-pixels SP. As such, the pixel definition layer 135 may include a light blocking material including at least one selected from among a color pigment, organic black, and carbon. The pixel definition layer 135 may further include a bank exposing each of emissive portions EM1, EM2 and a spacer provided in a portion of the upper surface of the bank as a pattern for preventing the bank from coming into contact with a deposition mask and preventing the bank from collapsing during the deposition process for forming the intermediate layer EL.

The intermediate layer EL may include a hole injection layer, a hole transport layer, an emission layer, an electron transport layer, and an electron injection layer. The intermediate layer EL may be formed of a plurality of stacks including a hole transport layer, an emission layer, and an electron transport layer, and may also be formed in a tandem structure including a charge generation layer between the stacks. The charge generation layer may include, for example, an n-type charge generation layer and a p-type charge generation layer.

The emission layer included in the intermediate layer EL may be provided differently for each sub-pixel. The emission layer EL may be composed of a red emission layer that emits red light, a green emission layer that emits green light, and a blue emission layer that emits blue light. The red emission layer, the green emission layer, and the blue emission layer may be disposed for respective sub-pixels SP on the anode E1.

For example, a red emission layer may be patterned and disposed in a red sub-pixel, a green emission layer may be patterned and disposed in a green sub-pixel, and a blue emission layer may be patterned and disposed in a blue sub-pixel. The present disclosure is not necessarily limited thereto, and at least two organic emission layers selected from among a red emission layer, a green emission layer, and a blue emission layer may be stacked and disposed in one sub-pixel SP.

The emission layer may, in some cases, be a white emission layer that emits white light. As such, the emission layer EL may be in the form of a common layer in which one or more layers are commonly disposed in the sub-pixels SP, rather than in a patterned form.

As described above, the intermediate layer EL may be disposed in a tandem structure of two or more stacks STACK. As such, each light emitting device ED5 may include a charge generation layer disposed between the stacks. The charge generation layer may be a common layer disposed on the front surface of the active area AA.

The cathode E2 may be formed by thinning a transparent electrode such as ITO, IZO, etc., or a reflective transparent electrode such as silver, a silver alloy, magnesium, a magnesium alloy, ytterbium (Yb), an ytterbium alloy, etc. In another embodiment, the cathode E2 may be formed at a low thickness or by partial removal from the transmissive portion TA region to increase transmittance in the transmissive portion TA. The cathode E2 may be a common layer that is commonly disposed in the sub-pixels SP and applies the same voltage. To this end, the cathode E2 may be provided to extend from the active area AA to a portion of the non-active area NA.

The cathode E2 may be a transparent electrode. The cathode E2 may include a transparent conductive material (TCO) such as ITO or IZO capable of transmitting light, or a semi-transmissive conductive material such as magnesium (Mg), silver (Ag), or an alloy of magnesium (Mg) and silver (Ag). When the cathode E2 is provided using a semi-transmissive conductive material, light extraction efficiency may be increased by virtue of microcavity design.

The top emission-type light emitting device ED was described above. However, the light emitting device ED of the present disclosure is not limited thereto, and may be provided in a bottom emission type in which light emitted from the intermediate layer EL is emitted toward the substrate 110. As such, the anode E1 may be composed of a transparent or translucent electrode material, and the cathode E2 may be composed of a reflective electrode material.

A capping layer (not shown) is further formed on the cathode E2 to protect the cathode E2 of the light emitting device ED and increase light extraction efficiency upward.

An encapsulation layer 150 is disposed on the light emitting device ED. The encapsulation layer 150 may serve to cover the active area AA and the non-active area NA to prevent oxygen or water from penetrating the light emitting device ED. Other layers, such as a capping layer, etc., may be interposed between the encapsulation layer 150 and the cathode E2 as necessary.

The encapsulation layer 150 may be composed of multiple layers. The encapsulation layer 150 may be configured such that an inorganic film including an inorganic insulating material and an organic film including an organic insulating material are alternately stacked. For example, the inorganic insulating material may include at least one selected from among silicon oxide, silicon nitride, and silicon oxynitride.

The organic insulating material may include at least one selected from the group consisting of polyethylene terephthalate, polyethylene naphthalate, polycarbonate, polyimide, polyethylene sulfonate, polyoxymethylene, polyarylate, and hexamethyldisiloxane.

The embodiments of the present disclosure enable selective mobility control between an area having a sensor portion and an area not having a sensor portion by varying the average mobility of active layers for each area.

The embodiments of the present disclosure may increase reliability by improving sensitivity to light by a multilayer structure of oxide semiconductor layers having differences in mobility in transistors including oxide semiconductors.

The embodiments of the present disclosure may exhibit high luminance characteristics as a driving transistor by further adding a high-mobility active layer to a sensor portion including transistors arranged at a relatively low density to improve the mobility of the transistors located in the sensor portion.

The light emitting display device according to embodiments of the present disclosure is configured such that a high-mobility active layer is further added to the transistors of a sensor portion so as to be located at a lower position compared to the transistors of a non-sensor portion, thus reducing the thickness of the buffer layer between the active pattern and the light blocking pattern in the transistors of the sensor portion, ultimately increasing the S-factor. Therefore, in the Vgs-Ids relationship, Ids are gradually changed in the range of Vgs representing low gradation, enabling sufficient low-gradation expression, thus achieving a wider range of gradation expressions when driving current is applied to the light emitting device.

The light emitting display device according to embodiments of the present disclosure may respond to high luminance characteristics required of the sensor portion because the transistors in the sensor portion have high mobility characteristics.

The light emitting display device according to embodiments of the present disclosure may exhibit improved optical reliability and reduced failure rate of transistors, and since active patterns having different structures may be manufactured through the same process, the amounts of materials used throughout the manufacturing process such as gases, etchants, etc., for manufacturing the display device may be reduced. Therefore, the present disclosure is intended to provide a light emitting display device capable of reducing greenhouse gas emissions during the manufacturing process.

In the light emitting display device according to embodiments of the present disclosure, it is possible to form active layers for each area through the same process, reducing the number of processes required for additional materials and lowering production energy, and also reducing greenhouse gas emissions during the manufacturing process through process optimization. Therefore, ESG (environmental/social/governance) goals may be achieved through process optimization.

A light emitting display device according to one embodiment of the present disclosure may comprise a substrate having a first area and a second area, first emissive portions at the first area, second emissive portions and transmissive portions at the second area, a first transistor at the first area, the first transistor comprising a first active pattern and a first gate electrode overlapping the first active pattern and a second transistor at the second area, the second transistor comprising a second active pattern and a second gate electrode overlapping the second active pattern. The second active pattern may have higher average mobility than the first active pattern and have multiple interfaces having differences in mobility.

In a light emitting display device according to one embodiment of the present disclosure, the second active pattern may comprise a first active layer, a second active layer, and a third active layer in a sequence close to the second gate electrode, the third active layer may have higher mobility than the second active layer. An edge of the third active layer may be identical to or adjacent to an edge of the second gate electrode in a plan view.

In a light emitting display device according to one embodiment of the present disclosure, mobility of the first active layer of the second active pattern may be greater than mobility of the second active layer of the second active pattern.

In a light emitting display device according to one embodiment of the present disclosure, the first active pattern may comprise a first active layer and a second active layer in a sequence close to the first gate electrode, and mobility of the first active layer of the first active pattern may be greater than mobility of the second active layer of the first active pattern.

In a light emitting display device according to one embodiment of the present disclosure, a thickness of the second active pattern overlapping the second gate electrode may be greater than a thickness of the first active pattern overlapping the first gate electrode.

In a light emitting display device according to one embodiment of the present disclosure, the first transistor may further comprise a first light blocking pattern overlapping the first active pattern, the first light blocking pattern located under the first active pattern, the second transistor may further comprise a second light blocking pattern overlapping the second active pattern, the second light blocking pattern located under the second active pattern. A second vertical distance between the second active pattern and the second light blocking pattern may be less than a first vertical distance between the first active pattern and the first light blocking pattern.

In a light emitting display device according to one embodiment of the present disclosure, the first light blocking pattern and the second light blocking pattern may be located at a same layer. A buffer layer may be provided between the first light blocking pattern and the second light blocking pattern, and the first active pattern and the second active pattern. The buffer layer may be in contact with a lower surface of the first active pattern at a flat upper surface thereof, and may be in contact with a lower surface of the second active pattern at a recessed upper surface thereof.

In a light emitting display device according to one embodiment of the present disclosure, each of the first active pattern and the second active pattern may comprise active layers with a multilayer oxide semiconductor structure, and a number of layers of the second active pattern may be greater than that of the first active pattern.

In a light emitting display device according to one embodiment of the present disclosure, each of the first active pattern and the second active pattern may comprise a first active layer and a second active layer with lower mobility than the first active layer beneath the first active layer, and the second active pattern may further comprise a third active layer with higher mobility than the second active layer beneath the second active layer.

In a light emitting display device according to one embodiment of the present disclosure, the third active layer may be closer to an edge of the second gate electrode than the second active layer in a plan view.

In a light emitting display device according to one embodiment of the present disclosure, the mobility of the first active layer and the third active layer may be 15 cm²/Vs or more, and the mobility of the second active layer may be 14 cm²/Vs or less.

In a light emitting display device according to one embodiment of the present disclosure, the first transistor may further comprise a first source-drain electrode and a second source-drain electrode connected to the first active layer with the first gate electrode therebetween, the second transistor may further comprise a third source-drain electrode and a fourth source-drain electrode connected to the first active layer with the second gate electrode therebetween. The third active layer may be located between the third source-drain electrode and the fourth source-drain electrode in a plan view.

In a light emitting display device according to one embodiment of the present disclosure, the first active layer and the third active layer may comprise at least one selected from SnO (Sn-oxide), FIZO (Fc—In—Zn-oxide), and ZnO (Zn-oxide).

In a light emitting display device according to one embodiment of the present disclosure, each of the first to third active layers may comprise IGZO (In—Ga—Zn-oxide), the first and third active layers may have an indium content greater than a gallium content, and the second active layer may have an indium content less than or equal to a gallium content.

In a light emitting display device according to one embodiment of the present disclosure, an arrangement density of the first emissive portions at the first area may be greater than an arrangement density of the second emissive portions at the second area.

In a light emitting display device according to one embodiment of the present disclosure, each of the first emissive portions may comprise a first light emitting device, and each of the second emissive portions may comprise a second light emitting device, an anode of the first light emitting device may be connected to the first transistor, and an anode of the second light emitting device may be connected to the second transistor.

In a light emitting display device according to one embodiment of the present disclosure, each of the first area and the second area may further comprise a switching transistor in which a gate electrode and a light blocking pattern are connected.

In a light emitting display device according to one embodiment of the present disclosure, a driving current of the second transistor at the second area may be greater than a driving current of the first transistor at the first area.

In a light emitting display device according to one embodiment of the present disclosure, the first active layer of the first active pattern and the first active layer of the second active pattern may be located at the same layer and the second active layer of the first active pattern and the second active layer of the second active pattern may be located at the same layer. The first and second gate electrodes may be located at the same layer.

As is apparent from the foregoing, a light emitting display device according to embodiments of the present disclosure has the following effects.

The embodiments of the present disclosure enable selective mobility control by varying the average mobility of active layers for each area.

The embodiments of the present disclosure are capable of increasing reliability by improving sensitivity to light by a multilayer structure of oxide semiconductor layers having differences in mobility in transistors including oxide semiconductors.

The embodiments of the present disclosure are capable of obtaining high luminance as a driving transistor by further adding a high-mobility active layer to a sensor portion having transistors arranged at a relatively low density to improve the mobility of the transistors located in the sensor portion.

The light emitting display device according to embodiments of the present disclosure is configured such that a high-mobility active layer is further added to the transistors of a sensor portion so as to be located at a lower position compared to the transistors of a non-sensor portion, reducing the thickness of the buffer layer between the active pattern and the light blocking pattern in the transistors of the sensor portion, ultimately increasing the S-factor. Therefore, in the Vgs-Ids relationship, sufficient low-gradation expression is possible due to a gentle change of Ids in the range of Vgs representing low gradation, enabling a wider range of gradation expressions when driving current is applied to the light emitting device.

The light emitting display device according to embodiments of the present disclosure can respond to high luminance required of the sensor portion because the transistors in the sensor portion have high mobility.

The light emitting display device according to embodiments of the present disclosure can exhibit improved optical reliability and reduced failure rate of transistors, and since active patterns having different structures can be manufactured through the same process, the amounts of materials used throughout the manufacturing process such as gases, etchants, etc., for manufacturing the display device can be reduced. Thus, the present disclosure is intended to provide a light emitting display device capable of reducing greenhouse gas emissions during the manufacturing process.

In the light emitting display device according to embodiments of the present disclosure, active layers for each area can be manufactured through the same process, reducing the number of processes required for additional materials and lowering production energy, and also reducing greenhouse gas emissions during the manufacturing process through process optimization. Therefore, ESG (environmental/social/governance) goals can be achieved through process optimization.

Those skilled in the art will understand that various modification and alternations are possible from the above description without departing from the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device, comprising:
a substrate having a first area and a second area;
first emissive portions at the first area;
second emissive portions and transmissive portions at the second area;
a first transistor at the first area, the first transistor comprising a first active pattern and a first gate electrode overlapping the first active pattern; and
a second transistor at the second area, the second transistor comprising a second active pattern and a second gate electrode overlapping the second active pattern,
wherein the second active pattern has higher average mobility than the first active pattern and multiple interfaces having differences in mobility.

2. The light emitting display device according to claim 1, wherein:
the second active pattern comprises a first active layer, a second active layer, and a third active layer in a sequence close to the second gate electrode,
the third active layer has higher mobility than the second active layer, and
an edge of the third active layer is identical to or adjacent to an edge of the second gate electrode in a plan view.

3. The light emitting display device according to claim 2, wherein mobility of the first active layer is greater than mobility of the second active layer.

4. The light emitting display device according to claim 1, wherein:
the first active pattern comprises a first active layer and a second active layer in a sequence close to the first gate electrode, and
mobility of the first active layer is greater than mobility of the second active layer.

5. The light emitting display device according to claim 1, wherein a thickness of the second active pattern overlapping the second gate electrode is greater than a thickness of the first active pattern overlapping the first gate electrode.

6. The light emitting display device according to claim 1, wherein:
the first transistor further comprises a first light blocking pattern overlapping the first active pattern, the first light blocking pattern located under the first active pattern,
the second transistor further comprises a second light blocking pattern overlapping the second active pattern, the second light blocking pattern located under the second active pattern, and
a second vertical distance between the second active pattern and the second light blocking pattern is less than a first vertical distance between the first active pattern and the first light blocking pattern.

7. The light emitting display device according to claim 6, wherein:
the first light blocking pattern and the second light blocking pattern are located at a same layer,
a buffer layer is provided between the first light blocking pattern and the second light blocking pattern, and the first active pattern and the second active pattern, and
the buffer layer is in contact with a lower surface of the first active pattern at a flat upper surface thereof, and is in contact with a lower surface of the second active pattern at a recessed upper surface thereof.

8. The light emitting display device according to claim 1, wherein:
each of the first active pattern and the second active pattern comprises active layers with a multilayer oxide semiconductor structure, and
a number of layers of the second active pattern is greater than that of the first active pattern.

9. The light emitting display device according to claim 8, wherein:
each of the first active pattern and the second active pattern comprises a first active layer and a second active layer with lower mobility than the first active layer beneath the first active layer, and
the second active pattern further comprises a third active layer with higher mobility than the second active layer beneath the second active layer.

10. The light emitting display device according to claim 9, wherein the third active layer is closer to an edge of the second gate electrode than the second active layer in a plan view.

11. The light emitting display device according to claim 9, wherein the mobility of the first active layer and the third active layer is 15 cm²/Vs or more, and the mobility of the second active layer is 14 cm²/Vs or less.

12. The light emitting display device according to claim 9, wherein:
the first transistor further comprises a first source-drain electrode and a second source-drain electrode connected to the first active layer with the first gate electrode therebetween,
the second transistor further comprises a third source-drain electrode and a fourth source-drain electrode connected to the first active layer with the second gate electrode therebetween, and
the third active layer is located between the third source-drain electrode and the fourth source-drain electrode in a plan view.

13. The light emitting display device according to claim 9, wherein the first active layer and the third active layer comprise at least one selected from SnO (Sn-oxide), FIZO (Fe—In—Zn-oxide), and ZnO (Zn-oxide).

14. The light emitting display device according to claim 9, wherein:
each of the first active layer, the second active layer and the third active layer comprises IGZO (In—Ga—Zn-oxide),
the first and third active layers have an indium content greater than a gallium content, and
the second active layer has an indium content less than or equal to a gallium content.

15. The light emitting display device according to claim 1, wherein an arrangement density of the first emissive portions at the first area is greater than an arrangement density of the second emissive portions at the second area.

16. The light emitting display device according to claim 1, wherein:
each of the first emissive portions comprises a first light emitting device, and each of the second emissive portions comprises a second light emitting device,
an anode of the first light emitting device is connected to the first transistor, and
an anode of the second light emitting device is connected to the second transistor.

17. The light emitting display device according to claim 1, wherein each of the first area and the second area further comprises a switching transistor in which a gate electrode and a light blocking pattern are connected.

18. The light emitting display device according to claim 1, wherein a driving current of the second transistor at the second area is greater than a driving current of the first transistor at the first area.

19. The light emitting display device according to claim 12, wherein the first active layer of the first active pattern and the first active layer of the second active pattern are located at the same layer, the second active layer of the first active pattern and the second active layer of the second active pattern are located at the same layer, and the first and second gate electrodes are located at the same layer.
